(19) United States
(12) Patent Application Publication
(10) Pub. No.: US 2013/0221471 A1
(43) Pub. Date: Aug. 29, 2013

(54) BACKSIDE ILLUMINATED IMAGE-SENSOR AND METHOD FOR MANUFACTURING THE SAME

(71) Applicant: Oh Jin JUNG, Seoul (KR)

(72) Inventor: Oh Jin JUNG, Seoul (KR)

(73) Assignee: Dongbu HiTek Co., Ltd., Seoul (KR)

(21) Appl. No.: 13/547,211

(22) Filed: Jul. 12, 2012

(30) Foreign Application Priority Data
Feb. 29, 2012 (KR) 10-2012-0021130

(51) Int. Cl. H01L 31/02

(52) U.S. Cl. 257/443; 438/64; 438/66; 257/E31.11

(57) ABSTRACT

A method for manufacturing a backside-illuminated image sensor may include forming an insulating layer having a predetermined depth in an inactive region of a front side of a semiconductor substrate and forming a photodetector in an active region of a front side of the semiconductor substrate having the insulating layer. Further, the method may include stacking a support substrate on and/or over the front side of the semiconductor substrate having the photodetector. Furthermore, the method may include performing back grinding on the rear side of the semiconductor substrate by using the insulating layer as the stop point.

The present application claims priority to Korean Patent Application No. 10-2012-0021130 (filed on Feb. 29, 2012), which is hereby incorporated by reference in its entirety.

### BACKGROUND

Light generated or reflected from objects existing in the natural world may have an associated inherent value in wavelength or similar measurement. An image sensor may be a device that takes the images of objects. An image sensor may use the properties of a semiconductor device that react with external energy. Pixels of the image sensor may sense the light generated from the objects and may convert the sensed light into an electric signal or values.

Some image sensors may be classified into either a CCD (Charge Coupled Device) based on a silicon semiconductor substrate or a CMOS image sensor using the technology of manufacturing a sub-micro CMOS (Complementary Metal Oxide Semiconductor).

A CCD may be a device in which MOS capacitors may be positioned very close to each other and charge carriers may be stored and carried to capacitors. However, a CCD may be driven in a relatively complicated manner and may consume a relatively high amount of power. Formation of a CCD may require a relatively large number of steps in a mask process. Therefore, it may be relatively difficult to implement a signal process circuit in a CCD chip compared to a CMOS image sensor (e.g. the ability to remove or minimize defects).

A CMOS image sensor may have a PD (Photo Diode) and a MOS transistor in unit cells and may implement an image by detecting signals in a switching method. A CMOS image sensor may have a relatively low manufacturing cost and power consumption compared to a CCD and may be relatively easily integrated with a peripheral chip. As described above, a CMOS image sensor may be manufactured by CMOS technology, such that it may be easily integrated with a peripheral system for amplifying and processing a signal. Therefore, it may be possible to minimize the manufacturing cost by implementation of CMOS image sensors. Further, the processing speed of a CMOS image sensor is relatively high and the power consumption is relatively low compared to a CCD image sensor (e.g. about 1% of the power consumption of a CCD in some applications).

An image sensor may be formed by ion-injecting photo diodes into a semiconductor substrate and the size of the photo diodes may be minimized to maximize the number of pixels without increasing the chip size and the general area of a photodetection unit may be minimized. A stack height may not be minimized to the extent of the minimization of the area of the photodetection unit, such that a backside-illuminated image sensor may minimize the step at the upper portion of the illumination unit and remove interference with light due to metal routing. The backside-illuminated image sensor may perform back grinding that grinds the backside of a semiconductor substrate in a predetermined thickness after forming a photodetector and wiring on and/or over the front side of the semiconductor substrate.

The back grinding, however, may have a problem in that it may be relatively difficult to ensure stable uniformity. Although it may be possible to expect favorable uniformity when using an SOI (Silicon On Insulator) wafer in which an insulating layer may be artificially formed between the surface and the base layer, there may be a problem in that the manufacturing cost of the image sensor may relatively expensive compared to an SOI wafer.

### SUMMARY

Embodiments relate to a method of manufacturing a backside-illuminated image sensor which may ensure stable uniformity of back grinding by forming an insulating layer. In embodiments, an insulating layer may be used as a stop point in back grinding, in an inactive region of a front side of a semiconductor substrate, and directed to a backside-illuminated image sensor manufactured by a manufacturing method.

In accordance with embodiments, a method of manufacturing a backside-illuminated image sensor that may include at least one of: (1) Forming an insulating layer having a predetermined depth in an inactive region of a front side of a semiconductor substrate. (2) Forming a photodetector in a front active region of the semiconductor substrate having the insulating layer. (3) Stacking a support substrate on and/or over the front side of the semiconductor substrate with the photodetector. (4) Performing back grinding on the rear side of the semiconductor substrate with the support substrate, by using the insulating layer as the stop point.

In embodiments, said forming of an insulating layer may include forming one or more trenches by patterning the front inactive region and forming the insulating layer by filling the trenches with an insulating material. In embodiments, said forming of trenches may form the trenches to have a width of approximately 1000 Å to 10000 Å and a depth of approximately 2 μm to 10 μm.

In accordance with embodiments, a backside-illuminated image sensor may include at least one of (1) A photodetector formed in an active region of a semiconductor substrate. (2) An insulating layer formed to have a predetermined depth in an inactive region of the semiconductor substrate and used as a stop point in back grinding of the rear side of the semiconductor substrate. (3) A support substrate supporting the semiconductor substrate.

The insulating layer may be formed by filling at least one or more trenches with an insulating material, in accordance with embodiments. The trenches may have a width of approximately 1000 Å to 10000 Å and a depth of approximately 2 μm to 10 μm, in accordance with embodiments. In accordance with the embodiments, it may be possible to ensure stable uniformity of back grinding by forming an insulating layer, which may be used as a stop point in back grinding, in a front inactive region of a semiconductor substrate.

### DRAWINGS

The above and other objects and features of the embodiments will become apparent from the following description given in conjunction with the accompanying drawings, in which:

FIGS. 1A to 1F are cross-sectional views illustrating a process of forming an insulating layer that may be used as a stop point of back grinding in an inactive region of a semiconductor substrate, in accordance with embodiments.

FIGS. 2A to 2E are cross-sectional views illustrating a process of forming a device isolation layer in the inactive region of the semiconductor substrate, in accordance with embodiments.

FIGS. 3A to 3H are cross sectional views illustrating processes in which photodetectors may be formed and back grinding may be performed on and/or over a rear side of the semiconductor substrate and then a color filter and a plurality of microlenses may be sequentially formed on and/or over the rear side of the semiconductor substrate, in accordance with embodiments.

### DESCRIPTION

Advantages and features of embodiments and methods of accomplishing the same may be understood more readily by reference to the following detailed description of embodiments and the accompanying drawings. The embodiments may, however, be embodied in many different forms and should not be construed as being limited to the embodiments set forth herein. Rather, these embodiments are provided so that this disclosure will be thorough and complete and will fully convey the concept of the invention to those skilled in the art, and embodiments will only be defined by the appended claims.

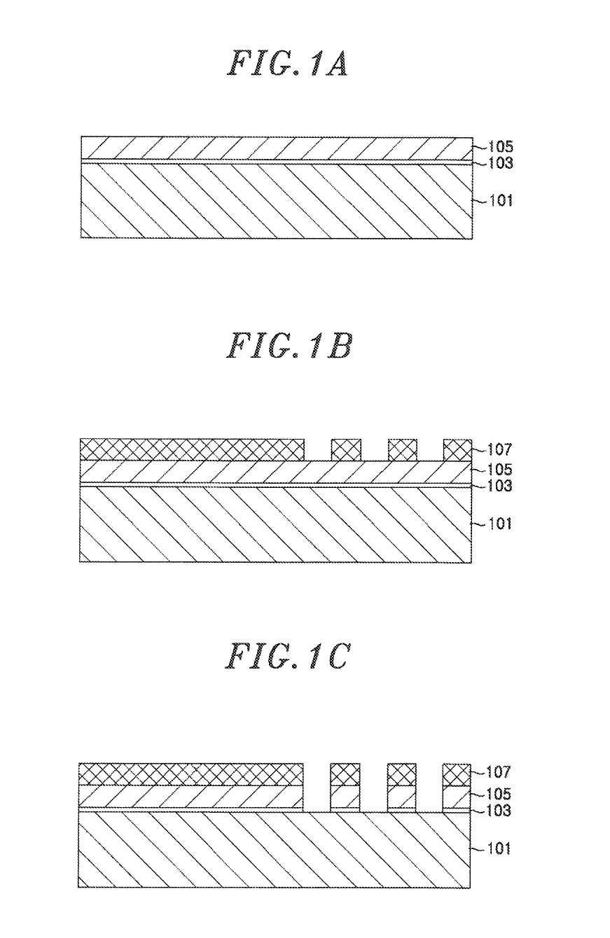

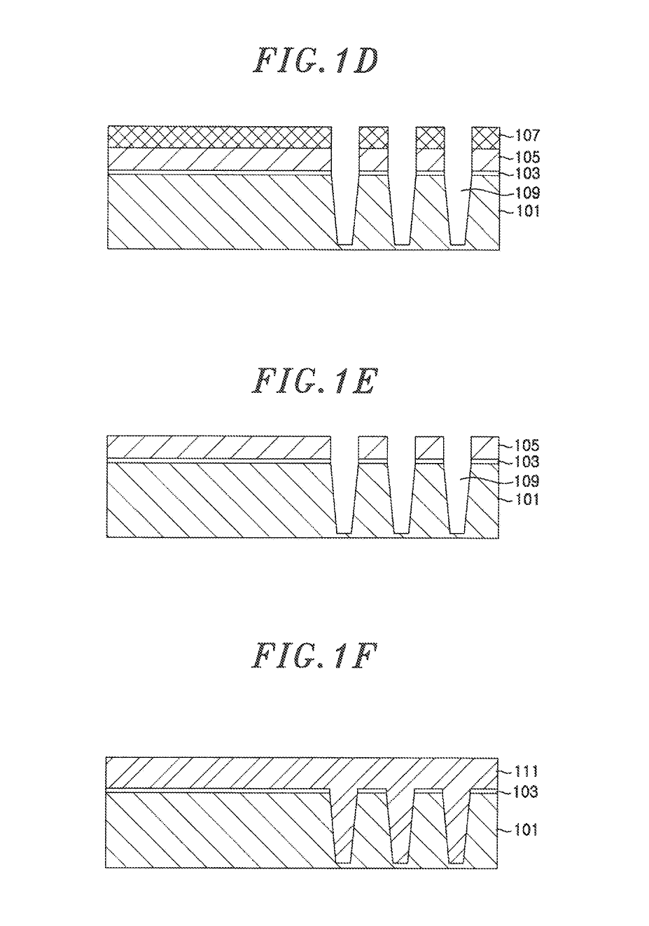

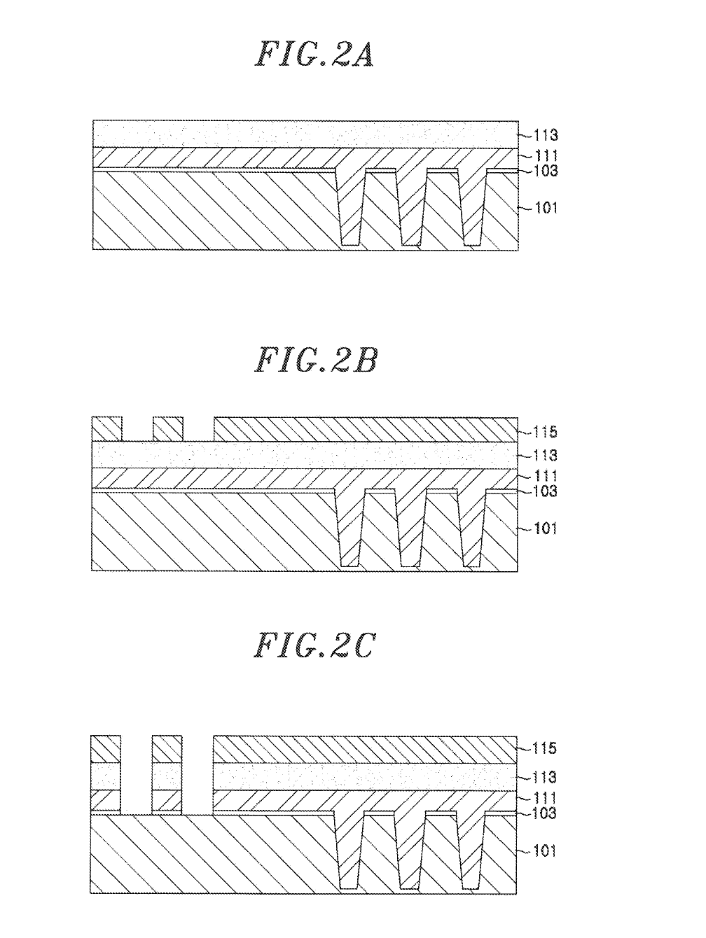

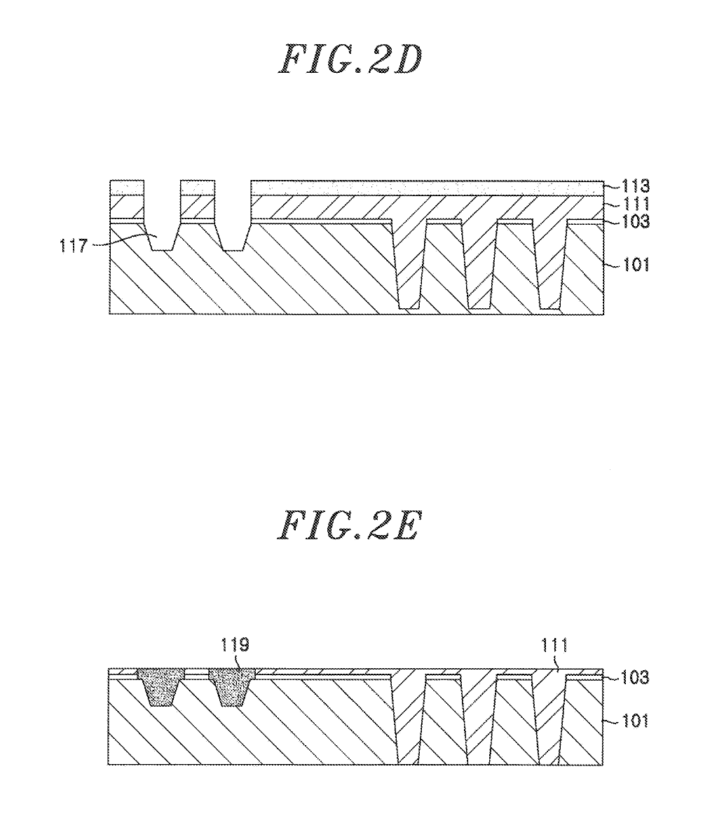

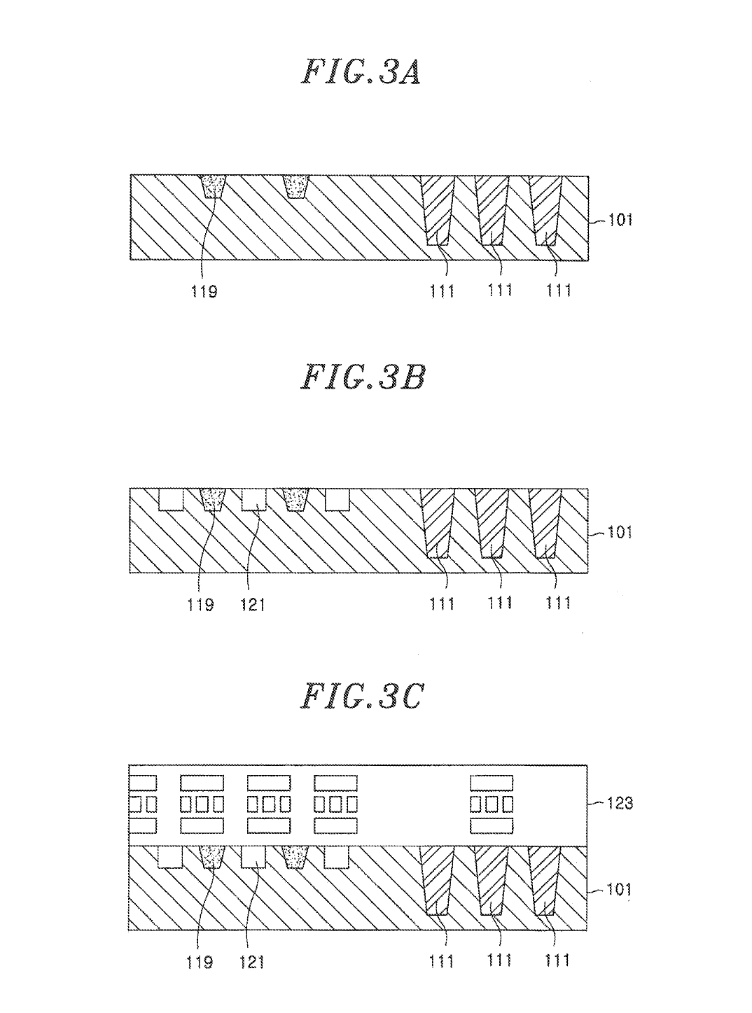

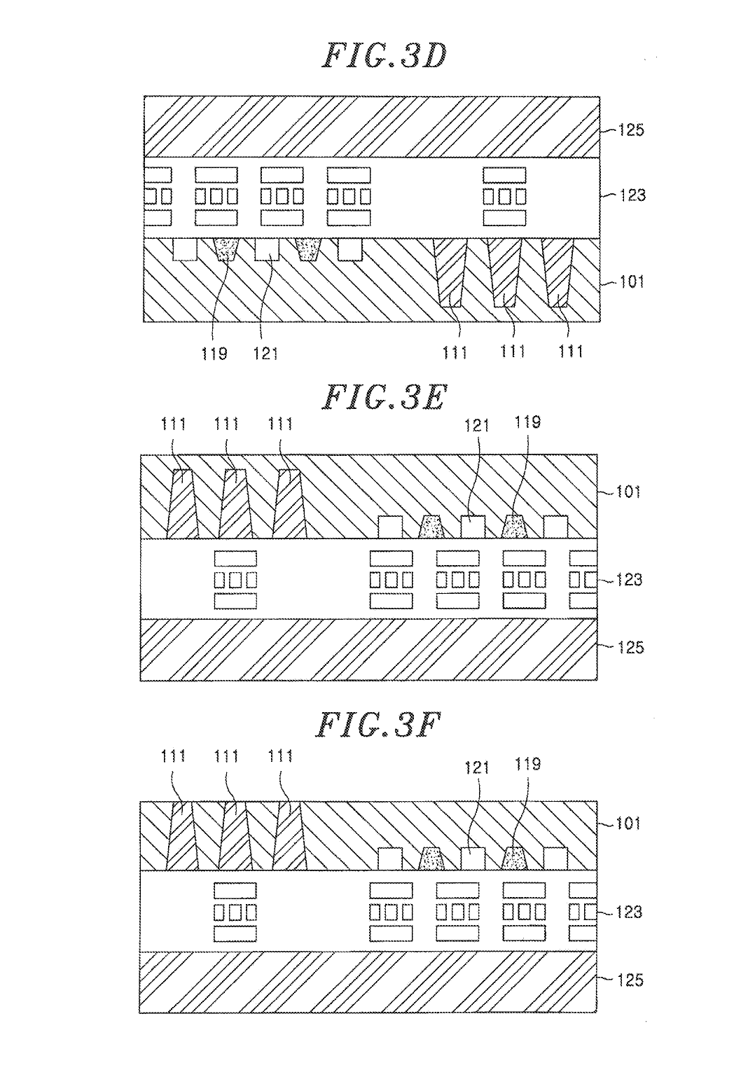

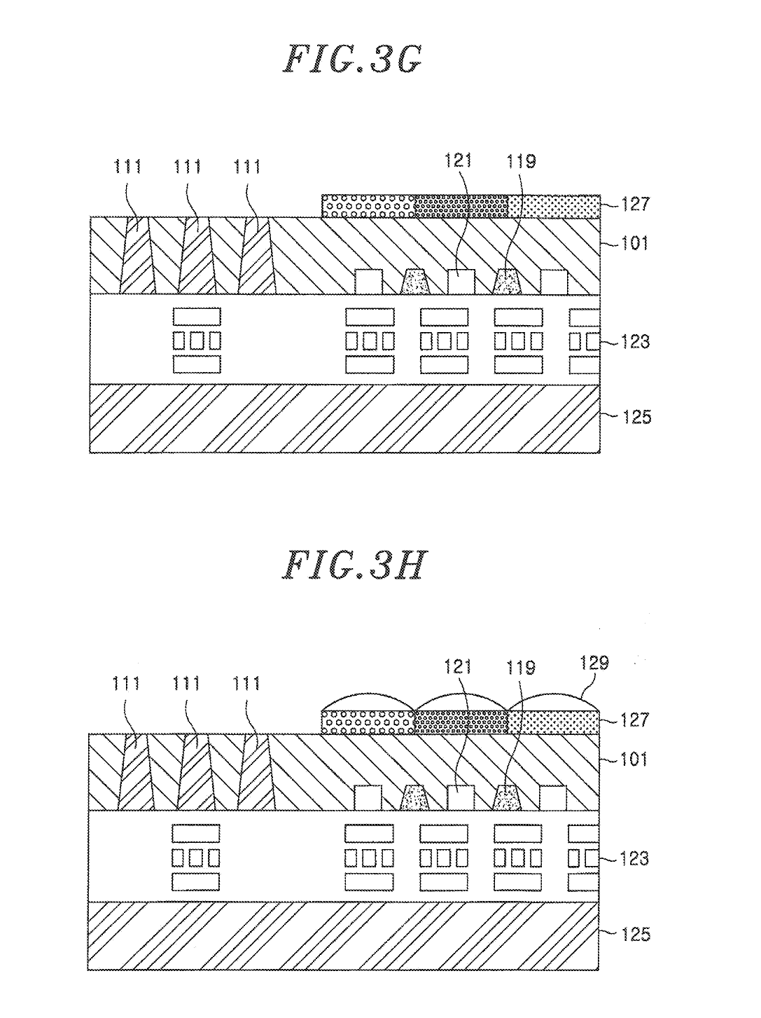

Example FIGS. 1A to 1F are cross sectional views illustrating a process of forming an insulating layer that may be used as a stop point of back grinding in an inactive region of a semiconductor substrate, in accordance with embodiments. Example FIGS. 2A to 2E are cross sectional views illustrating a process of forming a device isolation layer in the inactive region of the semiconductor substrate, in accordance with embodiments. Example FIGS. 3A to 3F are cross sectional views illustrating processes of performing back grinding on and/or over a rear side of the semiconductor substrate, in accordance with embodiments.

A method for manufacturing a backside-illuminated image sensor in accordance with embodiments may include at least one of: (1) Forming an insulating layer 111 having a predetermined depth in an inactive region of a front side of a semiconductor substrate 101. (2) Forming a photodetector 121 in an active region of a front side of the semiconductor substrate 101 having the insulating layer 111. (3) Stacking a support substrate 125 on and/or over the front side of the semiconductor substrate 101 having the photodetector 121. (4) Performing back grinding on the rear side of the semiconductor substrate 101 with the support substrate, by using the insulating layer 111 as a stop point.

The method for manufacturing the backside-illuminated image sensor having the configuration in accordance with embodiments will be described in more detail. A first pad oxide film 103 and a pad nitride film 105 may be sequentially formed on the semiconductor substrate 101, as illustrated in FIG. 1A, in accordance with embodiments. In embodiments, the first pad oxide film 103 is a film that may attenuate stress between the semiconductor substrate 101 and the pad nitride film 105. In embodiments, pad nitride film 103 may be substituted with a Si3N4 film and may be formed by a low furnace.

As shown in FIG. 1B, a first photoresist pattern 107, with an inactive region open where an insulating layer will be formed in subsequent processing, in accordance with embodiments. The first photoresist pattern 107 may be formed by back grinding on the pad nitride film 105. The first photoresist pattern 107 may be formed by applying a photoresist onto the pad nitride film 105 and then selectively patterning the first photoresist pattern 107 by using appropriate exposing and developing techniques.

As shown in FIG. 1C, the open regions of the pad nitride film 105 may be removed by using the first photoresist pattern 107 as a mask and then the open regions of the first pad oxide film 103 may be removed, in accordance with embodiments. In embodiments, the open regions of the pad nitride film 105 may be removed by reactive ion etching.

As shown in FIG. 1D, first trenches 109 are formed by removing the open regions of the semiconductor substrate 101 in a predetermined depth, using the first photoresist pattern 107 as a mask, in accordance with embodiments. In embodiments, the open regions of the semiconductor substrate 101 may be removed by reactive ion etching. Further, the first trenches 109 may be formed to have a width of approximately 1000 Å to 10000 Å and a depth of approximately 2 μm to 10 μm.

As shown in FIG. 1 E, cleaning may be performed after removing the first photoresist pattern 107, in accordance with embodiments. As shown in Fig. IF, an insulting layer 111 having a predetermined depth may be formed by filling the first trenches 109 formed in the semiconductor substrate 101 with an insulating material (e.g. TEOS), and the upper surface of the insulating layer 111 may be planarized. The insulating layer 1111 may be made of the same material as the pad nitride film 105. Further, the insulating layer 111 may be formed at scribe lanes or dummy die shot areas of the semiconductor substrate 101, in accordance with embodiments.

As shown in FIG. 2A, a second pad oxide film 113 may be formed on the insulating layer 111 formed in a predetermined depth on the semiconductor substrate 101, in accordance with embodiments. As shown in FIG. 2B, a second photoresist pattern 115 with a front active region open where a device isolation layer may be formed is formed on the semiconductor substrate 101, in accordance with embodiments. As shown in FIG. 2C, the open regions of the second pad oxide film 113 may be removed by using the second photoresist pattern 115 as a mask and then the open regions of the second pad oxide film 103 may be removed, in accordance with embodiments.

In embodiments, as shown in FIG. 2D second trenches 117 may be formed by removing the open regions of the semiconductor substrate 101 at a predetermined depth by using the patterned second pad oxide film 113 and insulating layer 111 as masks, and then the second photoresist pattern 115 may be removed. As shown in FIG. 2E, a device isolation layer 119 having a predetermined depth may be formed by filling the second trenches 117 formed in the semiconductor substrate 101 with an insulating material (e.g. TEOS) and the upper surface of the semiconductor substrate 101 with device isolation layer 119 may be planarized, in accordance with embodiments. In embodiments, it may be possible to planarize the semiconductor substrate 101 by performing chemical mechanical grinding until the device isolation layer 119 is exposed.

In embodiments, a photodetector may be formed by a method for manufacturing a backside-illuminated image sensor and a backside-illuminated image sensor may be formed by back grinding. As shown in FIG. 3A, the insulating layer 111 and the first pad oxide film 103 remaining on the upper surface of the semiconductor substrate 101 may be removed by cleaning the planarized semiconductor substrate 101, in accordance with embodiments. As shown in FIG. 3B, a photodetector 121 may be formed in a pixel region in the active region of the front side of the semiconductor substrate 101 having the insulating layer 111, in accordance with embodiments. As shown in FIG. 3C, a wiring 123 may be stacked on the front side of the semiconductor substrate 101 having the photodetector 121, in accordance with embodiments. The support substrate 125 may be stacked on the wiring 123. When the semiconductor substrate 101 is a P+ conductive type, it may be possible to form the photodetector 121 by injecting N+ ions, in accordance with embodiments.

As shown in FIG. 3E, the semiconductor substrate 101 having the wiring 123 the support substrate 125 may be turned upside down, in accordance with embodiments. In embodiments, as shown in FIG. 3F, back grinding may be performed on the rear side of the semiconductor substrate 101 by using the insulating layer 111 as a stop point to reduce the thickness of the semiconductor substrate 101, and may be stopped when the insulating layer 111 formed in a predetermined depth in the process of the front side may be exposed.

As shown in FIGS. 3G and 3H, a color filter 127 and a plurality of microlenses 129 may be sequentially formed on the back side of the semiconductor substrate 101, in accordance with embodiments. As a result, a backside-illuminated image sensor having wiring 123 on the front side of the semiconductor substrate 101 and having the microlens 129 on the back side of the semiconductor substrate 101 may be manufactured, in accordance with embodiments.

A backside-illuminated image sensor manufactured by the method of manufacturing a backside-illuminated image sensor in accordance with embodiments, which is described above, may include a photodetector formed in the active region of a semiconductor substrate, an insulating layer formed in an inactive region of the semiconductor substrate to have a predetermined depth and may be used as the stop position in back grinding of the back side of the semiconductor substrate, and a support substrate supporting the semiconductor substrate.

The insulating layer may be formed by filling at least one or more trenches with an insulating material and the insulating layer formed in the trench has a width of approximately 1000 Å to 10000 Å and a thickness of 2 μm to 10 μm, in accordance with embodiments. In embodiments, the insulating layer may be formed at a scribe lane or a dummy die shot area of the semiconductor substrate. It will be obvious and apparent to those skilled in the art that various modifications and variation can be made in the embodiments disclosed. Thus it is intended that the disclosed embodiments cover the obvious and apparent modifications and variations, provided that they are within the scope of the appended claims and their equivalents.

What is claimed is:

1. A method comprising:
forming an insulating layer having a predetermined depth in an inactive region of a front side of a semiconductor substrate;
forming a photodetector in the active region of the front side of the semiconductor substrate;
stacking a support substrate on the front side of the semiconductor substrate having the photodetector; and
performing back grinding on the rear side of the semiconductor substrate by using the insulating layer as the stop point to expose a portion of the insulating layer on the rear side of the semiconductor substrate.

2. The method of claim 1, wherein the method is a method of manufacturing a backside-illuminated image sensor.

3. The method of claim 1, wherein said forming of an insulating layer comprises:
forming at least one trench in the inactive region of the front side of the semiconductor; and
filling said at least one trench with an insulating material.

4. The method of claim 3, wherein said forming said at least one trench forms the trenches to have a width of approximately 1000 Å to approximately 10000 Å and a depth of approximately 2 μm to approximately 10 μm.

5. The method of claim 1, wherein said forming the insulating layer forms the insulating layer at at least one of a scribe lane and a dummy die shot area of the semiconductor substrate.

6. An apparatus comprising:
a photodetector formed in an active region of a semiconductor substrate on a front side of the semiconductor substrate;
an insulating layer formed to have a predetermined depth in an inactive region of the semiconductor substrate, wherein the insulating layer is exposed at a rear side of the semiconductor substrate; and
a support substrate supporting the semiconductor substrate.

7. The apparatus of claim 6, wherein the apparatus is a backside-illuminated image sensor.

8. The apparatus of claim 6, wherein the insulating layer is formed by filling at least one trench with an insulating material.

9. The apparatus of claim 8, wherein said at least one trench has a width of approximately 1000 Å to approximately 10000 Å and a depth of approximately 2 μm to approximately 10 μm.

10. The apparatus of claim 6, wherein the insulating layer is formed at at least one of a scribe lane and a dummy die shot area of the semiconductor substrate.

11. The apparatus of claim 6, wherein the insulating layer is configured to be used as a stop point in back grinding of the rear side of the semiconductor substrate.
